(19) United States
(12) Patent Application Publication
(10) Pub. No.: US 2026/0309777 A1
(43) Pub. Date: Oct. 8, 2026

(54) SEMICONDUCTOR DEVICES CONFIGURED FOR REPAIRING DEFECTIVE BUMPS

(71) Applicant: SK hynix Inc., Icheon-si Gyeonggi-do (KR)

(72) Inventors: Su Hyun OH, Icheon-si Gyeonggi-do (KR); Young Jun PARK, Icheon-si Gyeonggi-do (KR)

(73) Assignee: SK hynix Inc., Icheon-si Gyeonggi-do (KR)

(21) Appl. No.: 19/289,769

(22) Filed: Aug. 4, 2025

(30) Foreign Application Priority Data
Apr. 7, 2025 (KR) 10-2025-0045013

(51) Int. Cl. G01R 31/317; H10W 90/00; H10W 72/00

(52) U.S. Cl. CPC G01R 31/31705; H10W 90/00; H10W 72/01; H10W 90/722

(57) ABSTRACT

The present disclosure provides a semiconductor device including a plurality of core dies stacked over a base die. The base die includes a test interface circuit that performs a preset test based on a test information signal extracted from a test input signal and outputs a plurality of test result signals generated as a result of performing the preset test on a plurality of bumps. The test interface circuit shifts one or more of the plurality of test result signals to substitute a defective bump with a redundant bump when a defect occurs in one of the plurality of bumps.

### CROSS-REFERENCE TO RELATED APPLICATIONS

The present application claims priority under 35 U.S.C §119(a) to Korean Application No. 10-2025-0045013, filed in the Korean Intellectual Property Office on Apr. 7, 2025, the entire contents of which application is incorporated herein by reference.

### BACKGROUND

### 1. Technical Field

The present disclosure generally relates to semiconductor devices, and more particularly, to semiconductor devices related to repairing defective bumps.

### 2. Related Art

Stacked memory systems such as high bandwidth memory (HBM) devices are used in a wide range of applications due to their high bandwidth and energy efficiency. Unlike conventional memory system that uses parallel data buses, the stacked memory system includes a stacked memory device including a base chip and a plurality of memory chips interconnected by through silicon vias (TSVs). The stacked memory device includes a physical interface, such as a physical layer for communication with a processor. The physical layer is designed for high-speed data transmission and efficient communication.

### SUMMARY

In an embodiment, a memory device includes a plurality of core dies stacked over a base die. The base die may include a test interface circuit that performs a preset test based on a test information signal extracted from a test input signal and outputs a plurality of test result signals generated as a result of performing the preset test on a plurality of bumps. The test interface circuit may shift one or more of the plurality of test result signals to substitute a defective bump with a redundant bump when a defect occurs in one of the plurality of bumps.

In an embodiment, a memory system includes a test input decoder configured to receive a test input signal as serial data, extract channel selection information and instruction information from the test input signal, and output the channel selection information and the instruction information as a test information signal, a test control circuit configured to generate and output a plurality of test result signals according to a result of a test performed based on the test information signal, and a test output control circuit configured to output the plurality of test result signals as bump test output signals when the test is performed on an activated channel and no defect occurs in a plurality of bumps. The test output control circuit may shift the plurality of test result signals according to a bump repair signal to output the bump test output signal and a redundancy bump test output signal when a defect occurs in the plurality of bumps.

In an embodiment a memory system includes a plurality of core dies stacked over a base die. The base die may include a test interface circuit configured to perform a preset test based on a test information signal extracted from a test input signal and output a first bit of a test result signal and a second bit of the test result signal generated as a result of performing the test on a first bump and a second bump. The test interface circuit may output the first bit of the test result signal to the second bump and output the second bit of the test result signal to a redundancy bump when a defect occurs in the first bump.

### BRIEF DESCRIPTION OF THE DRAWINGS

FIG. 1 illustrates a base die according to an embodiment of the present disclosure.

FIG. 2 illustrates a test interface circuit according to an embodiment of the present disclosure.

FIG. 3 is a table showing test information signals generated in a test input decoder according to an embodiment of the present disclosure.

FIG. 4 illustrates a test output control circuit according to an embodiment of the present disclosure.

FIG. 5 illustrates a bump set according to an embodiment of the present disclosure.

FIG. 6 illustrates a first test output control circuit according to an embodiment of the present disclosure.

FIG. 7 illustrates a second test output control circuit according to an embodiment of the present disclosure.

FIG. 8 illustrates a sixteenth test output control circuit according to an embodiment of the present disclosure.

FIG. 9 illustrates a redundancy test output control circuit according to an embodiment of the present disclosure.

FIG. 10 illustrates an example of an operation in which a bump test output signal is output from a bump set while there are no defects in bumps.

FIGS. 11 and 12 illustrate examples of an operation in which a bump test output signal is output from a bump set while there are defects in bumps.

FIG. 13 is a block diagram illustrating a memory system according to an embodiment of the present disclosure.

### DETAILED DESCRIPTION

In the following description of embodiments, when a parameter is referred to as being “predetermined” or “preset” it may be intended to mean that a value of the parameter is determined in advance when the parameter is used in a process or an algorithm. The value of the parameter may be set when the process or the algorithm starts or may be set during a period in which the process or the algorithm is executed.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

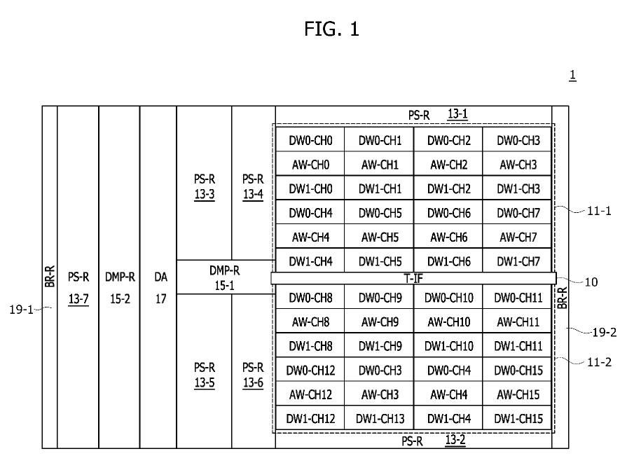

FIG. 1 illustrates a base die 1 according to an embodiment of the present disclosure.

As shown in FIG. 1, the base die 1 includes a test interface circuit (T-IF) 10, a first physical channel 11-1, a second physical channel 11-2, a first power region (PS-R) 13-1, a second power region 13-2, a third power region 13-3, a fourth power region 13-4,a fifth power region 13-5, a sixth power region 13-6, a seventh power region 13-7, a first probe pad region (DMP-R) 15-1, a second probe pad region 15-2, a test pad (DA) 17, a first bump(BR-R) 19-1, and a second bump 19-2.

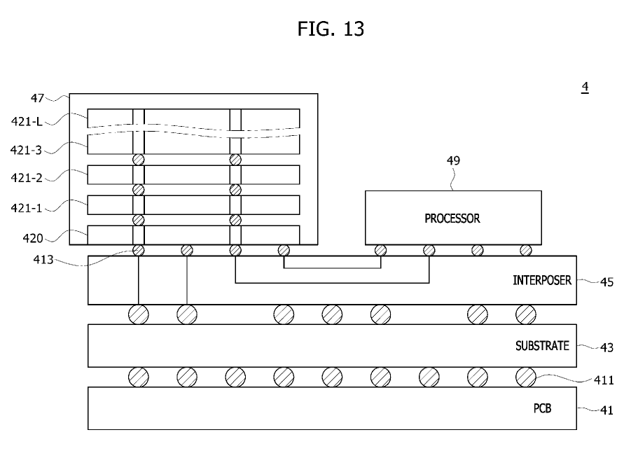

The test interface circuit 10 is implemented as a register transfer level (RTL) circuit and controls or tests operations of core dies, for example, core dies 421-1~421-L in FIG. 13, stacked over the base die 1. For example, the test interface circuit 10 may include RTL circuits that test the core dies based on the IEEE 1500 standard. As used herein, the tilde “~” indicates a range of components. For example, “421-1~421-L” indicates the core dies 421-1, 421-2, …, and 421-L shown in FIG. 13.

The first physical channel 11-1 controls the transmission of data, commands, and addresses between the core dies and a processor, for example, a processor 49 in FIG. 13, through a first channel. The first physical channel 11-1 includes data control circuits DW0-CH0 and DW1-CH0 that control the transmission of data through the first channel and a command address control circuit AW-CH0 that controls the transmission of commands and addresses through the first channel.

The first physical channel 11-1 controls the transmission of data, commands, and addresses between the core dies and the processor through a second channel. The first physical channel 11-1 includes data control circuits DW0-CH1 and DW1-CH1 that control the transmission of data through the second channel and a command address control circuit AW-CH1 that controls the transmission of commands and addresses through the second channel.

The first physical channel 11-1 controls the transmission of data, commands, and addresses between the core dies and the processor through a third channel. The first physical channel 11-1 includes data control circuits DW0-CH2 and DW1-CH2 that control the transmission of data through the third channel and a command address control circuit AW-CH2 that controls the transmission of commands and addresses through the third channel.

The first physical channel 11-1 controls the transmission of data, commands, and addresses between the core dies and the processor through a fourth channel. The first physical channel 11-1 includes data control circuits DW0-CH3 and DW1-CH3 that control the transmission of data through the fourth channel and a command address control circuit AW-CH3 that controls the transmission of commands and addresses through the fourth channel.

The first physical channel 11-1 controls the transmission of data, commands, and addresses between the core dies and the processor through a fifth channel. The first physical channel 11-1 includes data control circuits DW0-CH4 and DW1-CH4 that control the transmission of data through the fifth channel and a command address control circuit AW-CH4 that controls the transmission of commands and addresses through the fifth channel.

The first physical channel 11-1 controls the transmission of data, commands, and addresses between the core dies and the processor through a sixth channel. The first physical channel 11-1 includes data control circuits DW0-CH5 and DW1-CH5 that control the transmission of data through the sixth channel and a command address control circuit AW-CH5 that controls the transmission of commands and addresses through the sixth channel.

The first physical channel 11-1 controls the transmission of data, commands, and addresses between the core dies and the processor through a seventh channel. The first physical channel 11-1 includes data control circuits DW0-CH6 and DW1-CH6 that control the transmission of data through the seventh channel and a command address control circuit AW-CH6 that controls the transmission of commands and addresses through the seventh channel.

The first physical channel 11-1 controls the transmission of data, commands, and addresses between the core dies and the processor through an eighth channel. The first physical channel 11-1 includes data control circuits DW0-CH7 and DW1-CH7 that control the transmission of data through the eighth channel and a command address control circuit AW-CH7 that controls the transmission of commands and addresses through the eighth channel.

The second physical channel 11-2 controls the transmission of data, commands, and addresses between the core dies and the processor through a ninth channel. The second physical channel 11-2 includes data control circuits DW0-CH8 and DW1-CH8 that control the transmission of data through the ninth channel and a command address control circuit AW-CH8 that controls the transmission of commands and addresses through the ninth channel.

The second physical channel 11-2 controls the transmission of data, commands, and addresses between the core dies and the processor through a 10^{th} channel. The second physical channel 11-2 includes data control circuits DW0-CH9 and DW1-CH9 that control the transmission of data through the 10^{th} channel and a command address control circuit AW-CH9 that controls the transmission of commands and addresses through the 10^{th} channel.

The second physical channel 11-2 controls the transmission of data, commands, and addresses between the core dies and the processor through an 11^{th} channel. The second physical channel 11-2 includes data control circuits DW0-CH10 and DW1-CH10 that control the transmission of data through the 11^{th} channel and a command address control circuit AW-CH10 that controls the transmission of commands and addresses through the 11^{th} channel.

The second physical channel 11-2 controls the transmission of data, commands, and addresses between the core dies and the processor through a 12^{th} channel. The second physical channel 11-2 includes data control circuits DW0-CH11 and DW1-CH11 that control the transmission of data through the 12^{th} channel and a command address control circuit AW-CH11 that controls the transmission of commands and addresses through the 12^{th} channel.

The second physical channel 11-2 controls the transmission of data, commands, and addresses between the core dies and the processor through a 13^{th} channel. The second physical channel 11-2 includes data control circuits DW0-CH12 and DW1-CH12 that control the transmission of data through the 13^{th} channel and a command address control circuit AW-CH12 that controls the transmission of commands and addresses through the 13^{th} channel.

The second physical channel 11-2 controls the transmission of data, commands, and addresses between the core dies and the processor through a 14^{th} channel. The second physical channel 11-2 includes data control circuits DW0-CH13 and DW1-CH13 that control the transmission of data through the 14^{th} channel and a command address control circuit AW-CH13 that controls the transmission of commands and addresses through the 14^{th} channel.

The second physical channel 11-2 controls the transmission of data, commands, and addresses between the core dies and the processor through a 15^{th} channel. The second physical channel 11-2 includes data control circuits DW0-CH14 and DW1-CH14 that control the transmission of data through the 15^{th} channel and a command address control circuit AW-CH14 that controls the transmission of commands and addresses through the 15^{th} channel.

The second physical channel 11-2 controls the transmission of data, commands, and addresses between the core dies and the processor through a 16^{th} channel. The second physical channel 11-2 includes data control circuits DW0-CH15 and DW1-CH15 that control the transmission of data through the 16^{th} channel and a command address control circuit AW-CH15 that controls the transmission of commands and addresses through the 16^{th} channel.

Each of the first power region 13-1, the second power region 13-2, the third power region 13-3, the fourth power region 13-4, the fifth power region 13-5, the sixth power region 13-6, and the seventh power region 13-7 performs a power management function for a semiconductor device, for example, a semiconductor device 47 in FIG. 13, including the base die 1. The power management function may include an operation of generating an internal voltage from a power voltage supplied from a substrate, for example, a substrate 43 in FIG. 13, an operation of transmitting or transferring the power voltage and the internal voltage to the core dies using through vias, etc. Each of the first power region 13-1, the second power region 13-2, the third power region 13-3, the fourth power region 13-4, the fifth power region 13-5, the sixth power region 13-6, and the seventh power region 13-7 may include a low dropout regulator (LDO) that generates an internal voltage VPERI from a power voltage VDD, a power management IC (PMIC) that reduces power loss, a power grid for uniform power distribution, a decoupling capacitor that minimizes noise and ripple generated when power is supplied, and so forth. A position of each of the first power region 13-1, the second power region 13-2, the third power region 13-3, the fourth power region 13-4, the fifth power region 13-5, the sixth power region 13-6, and the seventh power region 13-7 included in the base die 1 may be implemented in various ways depending on the embodiment, and the number of power regions may also be modified in various ways depending on the embodiment.

Each of the first probe pad region 15-1 and the second probe pad region 15-2 includes a plurality of probe pads used to check the results measured in tests performed to confirm various electrical characteristics of the base die 1 in wafer level tests and package level tests. Each of the first probe pad region 15-1 and the second probe pad region 15-2 may be used to check signal integrity (SI) and power integrity (PI) during high-speed data transmission from the base die 1. Each of the first probe pad region 15-1 and the second probe pad region 15-2 may include micropillars with controlled density to minimize signal interference and power distribution. The positions of the first probe pad region 15-1 and the second probe pad region 15-2 may be set in various ways depending on the embodiment, and the number of probe pad regions may also be modified in various ways depending on the embodiment.

The test pad 17 may be utilized to directly access various test interface circuits such as built in self-test (BIST) and the IEEE 1500 standard from outside the semiconductor device to check the signal integrity (SI), power integrity (PI), and so forth in wafer test and packaging test, as well as to check for defects in the through vias. The position of the test pad 17 may be set in various ways depending on the embodiment.

Each of the first bump 19-1 and the second bump 19-2 connects the base die 1 and an interposer, for example, an interposer 45 in FIG. 13, to enable power and signal transmission between the base die 1 and the processor. In an embodiment, a base die 1 may be connected to an interposer through bumps (e.g., 19-1 and 19-2), for example, as shown in FIG. 13, the base die 420 (e.g., base die 1) is connected to the interposer 45 through bumps 413 (e.g., 19-1 and 19-2). Each of the first bump 19-1 and the second bump 19-2 may be connected to the through vias to and supply power and signals to the core dies. The positions of the first bump 19-1 and the second bump 19-2 may be set in various ways according to the embodiment, and the number of bumps may also be modified in various ways according to the embodiment.

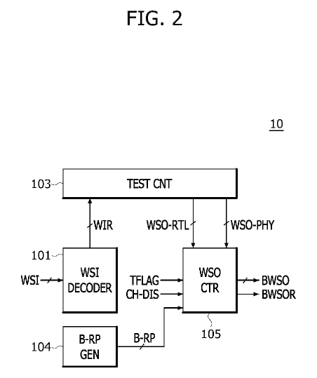

FIG. 2 illustrates a test interface circuit 10 according to an embodiment of the present disclosure, for example, as shown in FIG. 1.

As shown in FIG. 2, the test interface circuit 10 includes a test input decoder (WSI DECODER) 101, a test control circuit (TEST CNT) 103, a bump repair signal generation circuit (B-RP GEN) 104, and a test output control circuit (WSO CTR) 105.

The test input decoder 101 generates a test information signal WIR based on a test input signal WSI. The test input signal WSI may include information used to perform test. For example, the test input decoder 101 receives the test input signal WSI including channel selection information and instruction information as serial data for test using the IEEE 1500 standard. The test input decoder 101 decodes the test input signal WSI and outputs extracted channel selection information and instruction information as the test information signal WIR.

The test control circuit 103 is electrically connected to the test input decoder 101 and receives the test information signal WIR from the test input decoder 101. The test control circuit 103 controls a test corresponding to the instruction information included in the test information signal WIR to be performed on memory cell arrays inside the core dies connected to the channel selected by the test information signal WIR. The test control circuit 103 generates and outputs a test result signal WSO-PHY according to a result of the test performed by the test information signal WIR. The test control circuit 103 controls the performance of various tests other than the test using the IEEE 1500 standard, and generates and outputs an internal test result signal WSO-RTL according to the test result. It is only an example that the test result signal WSO-PHY is a test result signal using the IEEE 1500 standard and the internal test result signal WSO-RTL is a test result signal of one of various tests other than the IEEE 1500 test, but the present disclosure is not limited thereto. In an embodiment, the test result signals include the test result signal WSO-PHY and the internal test result signal WSO-RTL.

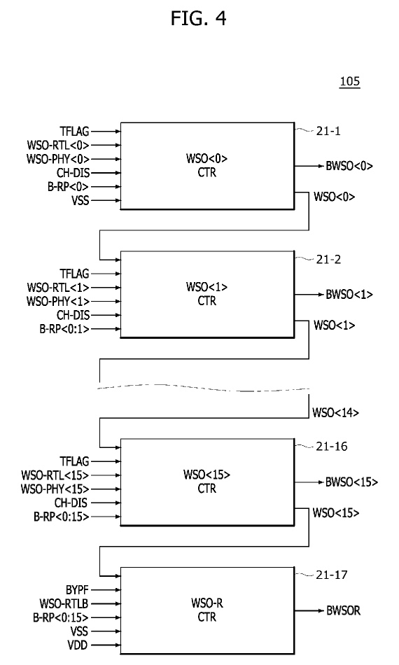

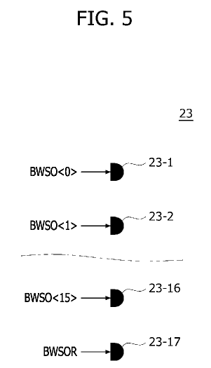

The bump repair signal generation circuit 104 generates a bump repair signal B-RP based on whether bumps, for example, bumps 23-1 to 23-16 in FIG. 5, from which a bump test output signal BWSO is output are defective. In an embodiment, a bump is defective when the bump provides an unexpected signal. The bump repair signal generation circuit 104 generates the bump repair signal B-RP having a logic level that is determined based on whether each bump from which the bump test output signal BWSO is output is defective. Defects in the bumps may be checked using a pre-test for checking for defects in general pads, and the bump repair signal generation circuit 104 stores information on whether the bumps are defective based on a result of the pre-test. For example, when a second bump among first bump to 16^{th} bump, for example, first bump 23-1 to 16^{th} bump 23-16 in FIG. 5, is defective, the bump repair signal generation circuit 104 generates only a second bump repair signal, for example, a second bump repair signal B-RP<1> in FIG. 4, corresponding to the second bump in an activated state, and generates a first bump repair signal, for example, a first bump repair signal B-RP<0> in FIG. 4, corresponding to the first bump and third to 16^{th} bump repair signal, for example, third to 16^{th} bump repair signals B-RP<2:15> in FIG. 4, corresponding to the third to sixteenth bumps in an inactivated state. As another example, when the 16^{th} bump among first to 16^{th} bumps, for example, the first to 16^{th} bumps 23-1 to 23-16 in FIG. 5 is defective, the bump repair signal generation circuit 104 generates only a 16^{th} bump repair signal, for example, a 16^{th} bump repair signal B-RP<15> in FIG. 4, corresponding to the 16^{th} bump in an activated state, and generates the first to 15^{th} bump repair signals, for example, first to 15^{th} bump repair signals B-RP<0:14> in FIG. 4, corresponding to the first to 15^{th} bumps in an inactivated state.

The test output control circuit 105 is electrically connected to the test control circuit 103 and the bump repair signal generation circuit 104, receives the test result signal WSO-PHY and the internal test result signal WSO-RTL from the test control circuit 103, and receives the bump repair signal B-RP from the bump repair signal generation circuit 104. The test output control circuit 105 generates the bump test output signal BWSO and a redundancy bump test output signal BWSOR from the test result signal WSO-PHY and the internal test result signal WSO-RTL based on a test flag TFLAG, a channel disable signal CH-DIS, and the bump repair signal B-RP. The test flag TFLAG may be activated for testing of the core dies based on the IEEE 1500 standard, but the present disclosure is not limited thereto. The channel disable signal CH-DIS may be activated when the channel being tested by the test interface circuit 10 is deactivated. The test output control circuit 105 receives the channel disable signal CH-DIS as deactivated and the bump repair signal B-RP as deactivated and receives the test flag TFALG as activated and outputs the test result signal WSO-PHY as the bump test output signal BWSO when a preset test, for example, a test based on the IEEE 1500 standard, is performed on an activated channel and no defects occur in the bumps. The test output control circuit 105 receives the channel disable signal CH-DIS as deactivated and receives the test flag TFLAG as activated, shifts the test result signal WSO-PHY according to the bump repair signal B-RP, and outputs the bump test output signal BWSO and the redundancy bump test output signal BWSOR when a preset test is performed on an activated channel and a defect occurs in the bumps.

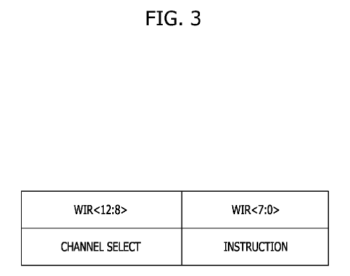

FIG. 3 is a table showing a test information signal WIR<12:0> generated in a test input decoder 101 according to an embodiment of the present disclosure, for example, as shown in FIG. 2.

As shown in FIG. 3, the test input decoder 101 decodes a test input signal WSI and outputs an extracted channel selection information and instruction information as the test information signal WIR<12:0>. More specifically, the test input decoder 101 decodes the test input signal WSI and outputs the extracted channel selection information as the test information signal WIR<12:8> and the instruction information as the test information signal WIR<7:0>.

FIG. 4 illustrates a test output control circuit 105 according to an embodiment of the present disclosure, for example, as shown in FIG. 2.

As shown in FIG. 4, the test output control circuit 105 includes first test output control circuit 21-1 to 16^{th} test output control circuit 21-16 and a redundancy test output control circuit 21-17.

The first test output control circuit 21-1 generates a first bit WSO<0> of a test output signal and a first bit BWSO<0> of a bump test output signal from a first bit WSO-PHY<0> of a test result signal and a first bit WSO-RTL<0> of an internal test result signal, based on a test flag TFLAG, a channel disable signal CH-DIS, and a first bit B-RP<0> of a bump repair signal. The first bit B-RP<0> of the bump repair signal may be activated when a defect occurs in a first bump, for example, a first bump 23-1 in FIG. 5. When a preset test, for example, a test based on the IEEE 1500 standard, is performed on an activated channel and no defect occurs in the first bump, the first test output control circuit 21-1 receives the channel disable signal CH-DIS as deactivated and the first bit B-RP<0> of the bump repair signal as deactivated, receives the test flag TFLAG as activated, and outputs the first bit WSO-PHY<0> of the test result signal as the first bit WSO<O> of the test output signal and the first bit BWSO<O> of the bump test output signal. When a preset test is performed on an activated channel and a defect occurs in the first bump, the first test output control circuit 21-1 receives the channel disable signal CH-DIS as deactivated and the first bit B-RP<0> of the bump repair signal as activated and the test flag TFLAG as activated, outputs the first bit WSO-PHY<0> of the test result signal as the first bit WSO<0> of the test output signal, and outputs the first bit BWSO<0> of the bump test output signal in a deactivated state, for example, a state set to a level of "ground voltage".

The second test output control circuit 21-2 is electrically connected to the first test output control circuit 21-1 and receives the first bit WSO<1> of the test output signal from the first test output control circuit 21-1. The second test output control circuit 21-2 generates a second bit WSO<1> of the test output signal and a second bit BWSO<1> of the bump test output signal from a second bit WSO-PHY<1> of the test result signal, a second bit WSO-RTL<1> of the internal test result signal, and the first bit WSO<0> of the test output signal based on the test flag TFLAG, the channel disable signal CH-DIS, a second bit B-RP<1> of the bump repair signal, and the first bit WSO<0> of the bump test output signal. The second bit B-RP<1> of the bump repair signal may be activated when a defect occurs in the second bump, for example, a second bump 23-2 in FIG. 5. When a preset test is performed on an activated channel and no defects occur in the first bump and the second bump, the second test output control circuit 21-2 receives the channel disable signal CH-DIS as deactivated and the first bit WSO<0> of the test output signal as deactivated, receives the test flag TFLAG as activated, and outputs the second bit WSO-PHY<1> of the test result signal as the second bit WSO<1> of the test output signal and the second bit BWSO<1> of the bump test output signal. When a preset test is performed on an activated channel and a defect occurs in the second bump, the second test output control circuit 21-2 receives the channel disable signal CH-DIS as deactivated, the second bit B-RP<1> of the bump repair signal as activated, and the test flag TFLAG as activated, outputs the second bit WSO-PHY<1> of the test result signal as the second bit WSO<1> of the test output signal, and outputs the second bit BWSO<1> of the bump test output signal in a deactivated state. When a preset test is performed on an activated channel and a defect occurs in the first bump, the second test output control circuit 21-2 receives the channel disable signal CH-DIS as deactivated, the second bit B-RP<1> of the bump repair signal as activated, and the test flag TFLAG as activated, outputs the second bit WSO-PHY<1> of the test result signal as the second bit WSO<1> of the test output signal, and outputs the first bit WSO<0> of the test output signal received from the first test output control circuit 21-1 as the second bit BWSO<1> of the bump test output signal.

The 16^{th} test output control circuit 21-16 is electrically connected to the 15^{th} test output control circuit 21-15 and receives a 15^{th} bit WSO<14> of the test output signal from the 15^{th} test output control circuit 21-15. The 16^{th} test output control circuit 21-16 generates a 16^{th} bit WSO<15> of the test output signal and a 16^{th} bit BWSO<15> of the bump test output signal from a 16^{th} bit WSO-PHY<15> of the test result signal, a 16^{th} bit WSO-RTL<15> of the internal test result signal, and the 15^{th} bit WSO<14> of the test output signal based on the test flag TFLAG, the channel disable signal CH-DIS, and the first to 16^{th} bits B-RP<0:15> of the bump repair signal. The 16^{th} bit B-RP<15> of the bump repair signal may be activated when a defect occurs in the 16^{th} bump, for example, a 16^{th} bump 23-16 in FIG. 5. When a preset test is performed on an activated channel and no defect occurs in the first bump to sixteenth bump, the 16^{th} test output control circuit 21-16 receives the channel disable signal CH-DIS as deactivated and the first to sixteenth bits B-RP<0:15> of the bump repair signal as deactivated, receives the test flag TFLAG as activated, and outputs the 16^{th} bit WSO-PHY<15> of the test result signal as the 16^{th} bit WSO<15> of the test output signal and the 16^{th} bit BWSO<15> of the bump test output signal. When a preset test is performed on an activated channel and a defect occurs in the 16^{th} bump, the 16^{th} test output control circuit 21-16 receives the channel disable signal CH-DIS as deactivated, the 16^{th} bit B-RP<15> of the bump repair signal as activated, and the test flag TFLAG as activated, outputs the 15^{th} bit WSO<14> of the test output signal as the 16^{th} bit WSO<15> of the test output signal, and outputs the 16^{th} bit BWSO<15> of the bump test output signal in a deactivated state. When a preset test is performed on an activated channel and a defect occurs in one of the first bump to the fifteenth bump, the 16^{th} test output control circuit 21-16 receives the channel disable signal CH-DIS as deactivated, the test flag TFLAG as activated, and an activated bit corresponding to a defective bump among the first to 15^{th} bits B-RP<0:14> of the bump repair signal, outputs the 16^{th} bit WSO-PHY<15> of the test result signal as the 16^{th} bit WSO<15> of the test output signal, and outputs the 15^{th} bit WSO<14> of the test output signal received from the 15^{th} test output control circuit 21-15 as the 16^{th} bit BWSO<15> of the bump test output signal.

The redundancy test output control circuit 21-17 is electrically connected to the 16^{th} test output control circuit 21-16 and receives the 16^{th} bit WSO<15> of the test output signal from the 16^{th} test output control circuit 21-16. The redundancy test output control circuit 21-17 generates a redundancy bump test output signal BWSOR from a bypass output signal WSO-RTLB and a ground voltage VSS based on a bypass flag BYPF and the first to 16^{th} bits B-RP<0:15> of the bump repair signal. The redundancy test output control circuit 21-17 generates the redundancy bump test output signal BWSOR that is deactivated by the ground voltage VSS when a preset test is performed on an activated channel and no defect occurs in the first bump to the 16^{th} bump. When a preset test is performed on an activated channel and a defect occurs in one of the first bump to the 16^{th} bump, the redundancy test output control circuit 21-17 receives the bypass flag BYPF as deactivated and an activated bit corresponding to the defective bump among the first to 16^{th} bits B-RP<0:15> of the bump repair signal and outputs the 16^{th} bit WSO<15> of the test output signal as the redundancy bump test output signal BWSOR.

FIG. 5 illustrates a bump set 23 according to an embodiment of the present disclosure.

As shown in FIG. 5, the bump set 23 includes a first bump 23-1 to a 17^{th} bump 23-17.

When no defect occurs in the first bump 23-1, a first bit BWSO<0> of a bump test output signal generated from a first bit WSO<0> of a test output signal is output through the first bump 23-1. When a defect occurs in the first bump 23-1, the first bit BWSO<0> of the bump test output signal is generated in a deactivated state.

When no defect occurs in the first bump 23-1 and the second bump 23-2, a second bit BWSO<1> of the bump test output signal generated from a second bit WSO<1> of the test output signal is output through the second bump 23-2. When a defect occurs in the first bump 23-1, the second bit BWSO<1> of the bump test output signal generated from the first bit WSO<0> of the test output signal is output through the second bump 23-2. When a defect occurs in the second bump 23-2, the second bit BWSO<1> of the bump test output signal is generated in a deactivated state.

When no defect occurs in the first bump 23-1 to the 16^{th} bump 23-16, a 16^{th} bit BWSO<15> of the bump test output signal generated from a 16^{th} bit WSO<15> of the test output signal is output through the 16^{th} bump 23-16. When a defect occurs in one of the first bump 23-1 to the 15^{th} bump 23-15, a 15^{th} bit BWSO<14> of the bump test output signal generated from a 15^{th} bit WSO<14> of the test output signal is output through the 16^{th} bump 23-16. When a defect occurs in the 16^{th} bump 23-16, the 16^{th} bit BWSO<15> of the bump test output signal is generated in a deactivated state.

When no defect occurs in the first bump 23-1 to the 16^{th} bump 23-16, the redundancy bump test output signal BWSOR is generated in a deactivated state. When a defect occurs in one of the first bump 23-1 to the 16^{th} bump 23-16, the redundancy bump test output signal BWSOR generated from the 16^{th} bit WSO<15> of the test output signal is output through the 17^{th} bump 23-17.

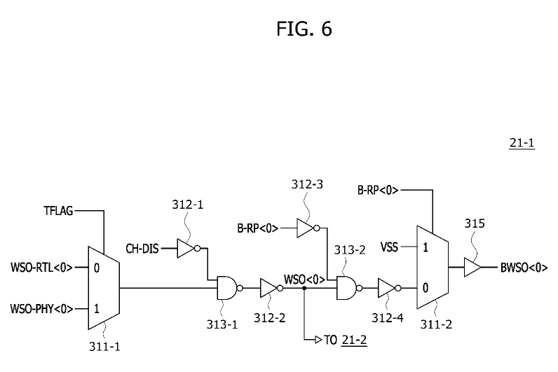

FIG. 6 illustrates a first test output control circuit 21-1 according to an embodiment of the present disclosure, for example, as shown in FIG. 4.

As shown in FIG. 6, the first test output control circuit 21-1 includes selectors 311-1 and 311-2, inverters 312-1, 312-2, 312-3, and 312-4, NAND gates 313-1 and 313-2, and a driver 315. The selector 311-1 selects and outputs one of a first bit WSO-PHY<0> of a test result signal and a first bit WSO-RTL<0> of an internal test result signal based on a test flag TFLAG. The selector 311-1 selects and outputs the first bit WSO-PHY<0> of the test result signal when a preset test, for example, a test based on the IEEE 1500 standard, is performed. The inverter 312-1 inversely buffers a channel disable signal CH-DIS and outputs an inversely buffered channel disable signal CH-DIS. The NAND gate 313-1 and the inverter 312-2 receive an output signal of the selector 311-1 and an output signal of the inverter 312-1 and perform a logical AND operation to generate a first bit WSO<0> of a test output signal. The NAND gate 313-1 and the inverter 312-2 buffer the first bit WSO-PHY<0> of the test result signal to generate the first bit WSO<0> of the test output signal and output the first bit WSO<0> of the test output signal to a second test output control circuit 21-2, for example, the second test output control circuit 21-2 in FIG. 4 when a preset test is performed on an activated channel. The inverter 312-3 inversely buffers a first bit B-RP<0> of a bump repair signal and outputs an inversely buffered first bit B-RP<0> of the bump repair signal. The NAND gate 313-2 and the inverter 312-4 receive an output signal of the inverter 312-3 and the first bit WSO<0> of the test output signal and perform a logical AND operation. The NAND gate 313-2 and the inverter 312-4 buffer and output the first bit WSO<0> of the test output signal when no defect occurs in the first bump and the first bit B-RP<0> of the bump repair signal deactivated at a logic low level is received by the inverter 312-3. The NAND gate 313-2 and the inverter 312-4 output a signal at a logic low level when a defect occurs in the first bump and the first bit B-RP<0> of the bump repair signal activated at a logic high level is received by the inverter 312-3. The selector 311-2 selects and outputs one of the ground voltage VSS and an output signal of the inverter 312-4 based on the first bit B-RP<0> of the bump repair signal. When no defect occurs in the first bump and the first bit B-RP<0> of the bump repair signal deactivated at a logic low level is received, the selector 311-2 selects and outputs the first bit WSO<O> of the test output signal buffered by the NAND gate 313-2 and the inverter 312-4. The selector 311-2 selects and outputs the ground voltage VSS when a defect occurs in the first bump and the first bit B-RP<0> of the bump repair signal activated at a logic high level is received. The driver 315 drives a first bit BWSO<0> of a bump test output signal according to an output signal of the selector 311-2.

The first test output control circuit 21-1 configured as described above receives the channel disable signal CH-DIS deactivated at a logic low level, the first bit B-RP<0> of the bump repair signal deactivated at a logic low level, and the test flag TFLAG activated at a logic high level and outputs the first bit WSO-PHY<0> of the test result signal as the first bit WSO<0> of the test output signal and the first bit BWSO<0> of the bump test output signal when a preset test is performed on an activated channel and no defect occurs in the first bump. In addition, when a preset test is performed on an activated channel and a defect occurs in the first bump, the first test output control circuit 21-1 receives the channel disable signal CH-DIS deactivated at a logic low level and the first bit B-RP<0> of the bump repair signal activated at a logic high level and the test flag TFLAG activated at a logic high level, outputs the first bit WSO-PHY<0> of the test result signal as the first bit WSO<O> of the test output signal, and outputs the first bit BWSO<O> of the bump test output signal deactivated at a logic low level.

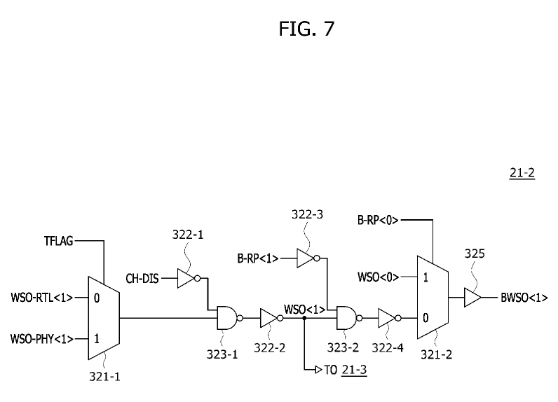

FIG. 7 illustrates a second test output control circuit 21-2 according to an embodiment of the present disclosure, for example, as shown in FIG. 4.

As shown in FIG. 7, the second test output control circuit 21-2 includes selectors 321-1 and 321-2, inverters 322-1, 322-2, 322-3, and 322-4, NAND gates 323-1 and 323-2, and a driver 325. The selector 321-1 selects and outputs one of a second bit WSO-PHY<1> of a test result signal and a second bit WSO-RTL<1> of an internal test result signal based on a test flag TFLAG. The selector 321-1 selects and outputs the second bit WSO-PHY<1> of the test result signal when a preset test, for example, a test based on the IEEE 1500 standard, is performed. The inverter 322-1 inversely buffers a channel disable signal CH-DIS and outputs an inversely buffered channel disable signal CH-DIS. The NAND gate 323-1 and the inverter 322-2 receive an output signal of the selector 321-1 and an output signal of the inverter 322-1 and perform a logical AND operation to generate a second bit WSO<1> of a test output signal. The NAND gate 323-1 and the inverter 322-2 buffer the second bit WSO-PHY<1> of the test result signal, generate the second bit WSO<1> of the test output signal, and output the generated second bit WSO<1> of the test output signal to a third test output control circuit, for example, the third test output control circuit 21-3 in FIG. 4 when a preset test is performed on an activated channel. The inverter 322-3 inversely buffers and outputs the second bit B-RP<1> of the bump repair signal. The NAND gate 323-2 and the inverter 322-4 receive an output signal of the inverter 322-3 and the second bit WSO<1> of the test output signal and perform a logical AND operation. The NAND gate 323-2 and the inverter 322-4 buffer and output the second bit WSO<1> of the test output signal when no defect occurs in a second bump and the second bit B-RP<1> of the bump repair signal deactivated at a logic low level is received by the inverter 322-3. The NAND gate 323-2 and the inverter 322-4 output a signal of a logic low level when a defect occurs in the second bump and the second bit B-RP<1> of the bump repair signal activated at a logic high level is received by the inverter 322-3. The selector 321-2 selects and outputs one of the first bit WSO<0> of the test output signal received from a first test output control circuit, for example, the first test output control circuit 21-1 in FIG. 4 and an output signal of the inverter 322-4 based on the first bit B-RP<0> of the bump repair signal. The selector 321-2 selects and outputs the second bit WSO<1> of the test output signal buffered through the NAND gate 323-2 and the inverter 322-4 when no defect occurs in the first bump and the first bit B-RP<0> of the bump repair signal deactivated at a logic low level is received. The selector 321-2 selects and outputs the first bit WSO<0> of the test output signal when a defect occurs in the first bump and the first bit B-RP<0> of the bump repair signal activated at a logic high level is received. The driver 325 drives the second bit BWSO<1> of the bump test output signal according to an output signal of the selector 321-2.

The second test output control circuit 21-2 configured as described above receives the channel disable signal CH-DIS deactivated at a logic low level, the first and second bits B-RP<0:1> of the bump repair signal deactivated at a logic low level, and the test flag TFLAG activated at a logic high level and outputs the second bit WSO-PHY<1> of the test result signal as the second bit WSO<1> of the test output signal and the second bit BWSO<1> of the bump test output signal when a preset test is performed on an activated channel and no defect occurs in the first bump and the second bump. In addition, when a preset test is performed on an activated channel and a defect occurs in the second bump, the second test output control circuit 21-2 receives the channel disable signal CH-DIS deactivated at a logic low level, the second bit B-RP<1> of the bump repair signal activated at a logic high level, and the test flag TFLAG activated at a logic high level, outputs the second bit WSO-PHY<1> of the test result signal as the second bit WSO<1> of the test output signal, and outputs the second bit BWSO<1> of the bump test output signal deactivated at a logic low level. In addition, when a preset test is performed on the activated channel and a defect occurs in the first bump, the second test output control circuit 21-2 receives the channel disable signal CH-DIS deactivated at a logic low level, the first bit B-RP<0> of the bump repair signal activated at a logic high level, and the test flag TFLAG activated at a logic high level, outputs the second bit WSO-PHY<1> of the test result signal as the second bit WSO<1> of the test output signal, and outputs the first bit WSO<0> of the test output signal received from the first test output control circuit 21-1 as the second bit BWSO<1> of the bump test output signal.

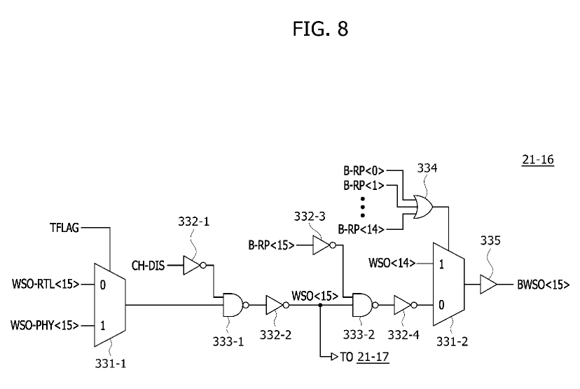

FIG. 8 illustrates a 16^{th} test output control circuit 21-16 according to an embodiment of the present disclosure, for example, as shown in FIG. 4.

As shown in FIG. 8, the 16^{th} test output control circuit 21-16 includes selectors 331-1 and 331-2, inverters 332-1, 332-2, 332-3, and 332-4, NAND gates 333-1 and 333-2, an OR gate 334, and a driver 335. The selector 331-1 selects and outputs one of a 16^{th} bit WSO-PHY<15> of a test result signal and a 16^{th} bit WSO-RTL<15> of an internal test result signal based on a test flag TFLAG. The selector 331-1 selects and outputs the 16^{th} bit WSO-PHY<15> of the test result signal when a preset test, for example, a test based on the IEEE 1500 standard, is performed. The inverter 332-1 inversely buffers a channel disable signal CH-DIS and outputs an inversely buffered channel disable signal CH-DIS. The NAND gate 333-1 and the inverter 332-2 receive an output signal of the selector 331-1 and an output signal of the inverter 332-1 and perform a logical AND operation to generate the 16^{th} bit WSO<15> of the test output signal. The NAND gate 333-1 and the inverter 332-2 buffer the 16^{th} bit WSO-PHY<15> of the test result signal to generate a 16^{th} bit WSO<15> of the test output signal, and output the 16^{th} bit WSO<15> of the test output signal to a redundancy test output control circuit, for example, the redundancy test output control circuit 21-17 when a preset test is performed on an activated channel. The inverter 332-3 inversely buffer a 16^{th} bit B-RP<15> of the bump repair signal and outputs an inversely buffered 16^{th} bit B-RP<15> of the bump repair signal. The NAND gate 333-2 and the inverter 332-4 receive an output signal of the inverter 332-3 and the 16^{th} bit WSO<15> of the test output signal and perform a logical AND operation. The NAND gate 333-2 and the inverter 332-4 buffer and output the 16^{th} bit WSO<15> of the test output signal when no defect occurs in a 16^{th} bump and the 16^{th} bit B-RP<15> of the bump repair signal deactivated at a logic low level is received by the inverter 332-3. The NAND gate 333-2 and the inverter 332-4 output a signal at a logic low level when a defect occurs in the 16^{th} bump and the 16^{th} bit B-RP<15> of the bump repair signal activated at a logic high level is received by the inverter 332-3. The OR gate 334 receives the first to fifteenth bits B-RP<0:14> of the bump repair signal and performs a logical OR operation. The OR gate 334 outputs a signal of a logic low level when no defect occurs in the first to fifteenth bumps, and outputs a signal of a logic high level when a defect occurs in one of the first to fifteenth bumps. The selector 331-2 selects and outputs one of a 15^{th} bit WSO<14> of the test output signal received from a 15^{th} test output control circuit, for example, the 15^{th} test output control circuit 21-14 and an output signal of the inverter 332-4 based on an output signal of the OR gate 334. The selector 331-2 selects and outputs the 16^{th} bit WSO<15> of the test output signal buffered through the NAND gate 333-2 and the inverter 332-4 when no defects occur in the first to fifteenth bumps and the output signal of the OR gate 334 is at a logic low level. The selector 331-2 selects and outputs the 15^{th} bit WSO<14> of the test output signal when a defect occurs in one of the first to fifteenth bumps and the output signal of the OR gate 334 is at a logic high level. The driver 335 drives a 16^{th} bit BWSO<15> of the bump test output signal according to an output signal of the selector 331-2.

The 16^{th} test output control circuit 21-16 configured as described above receives the channel disable signal CH-DIS deactivated at a logic low level and the first to 16^{th} bits B-RP<0:15> of the bump repair signal deactivated at a logic low level, receives the test flag TFLAG activated at a logic high level, and outputs the 16^{th} bit WSO-PHY<15> of the test result signal as the 16^{th} bit WSO<15> of the test output signal and the 16^{th} bit BWSO<15> of the bump test output signal when a preset test is performed on an activated channel and no defect occurs in the first bump to the 16^{th} bump. In addition, when a preset test is performed on an activated channel and a defect occurs in the 16^{th} bump, the 16^{th} test output control circuit 21-16 receives the channel disable signal CH-DIS deactivated at a logic low level, a 16^{th} bit B-RP<15> of the bump repair signal activated at a logic high level, and the test flag TFLAG activated at a logic high level, outputs the 16^{th} bit WSO-PHY<15> of the test result signal as the 16^{th} bit WSO<15> of the test output signal, and outputs the 16^{th} bit BWSO<15> of the bump test output signal deactivated at a logic low level. In addition, when a preset test is performed on an activated channel and a defect occurs in one of the first bump to 15^{th} bump, the 16^{th} test output control circuit 21-16 receives the channel disable signal CH-DIS deactivated at a logic low level, the test flag TFLAG activated at a logic high level, and a signal activated at a logic high level among the first to 15^{th} bits B-RP<0:14> of the bump repair signal, outputs the 16^{th} bit WSO-PHY<15> of the test result signal as the 16^{th} bit WSO<15> of the test output signal, and outputs the 15^{th} bit WSO<14> of the test output signal received from a 15^{th} test output control circuit, for example, the 15^{th} test output control circuit 21-15 in FIG. 4 as the 16^{th} bit BWSO<15> of the bump test output signal.

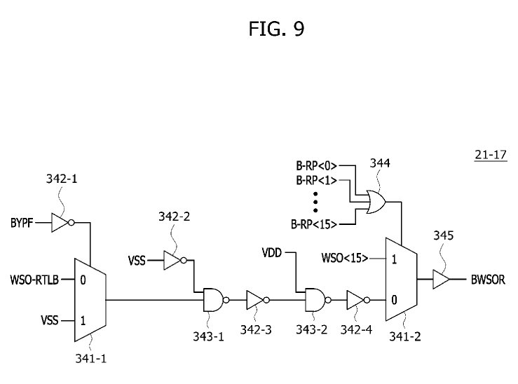

FIG. 9 illustrates a redundancy test output control circuit 21-17 according to an embodiment of the present disclosure, for example, as shown in FIG. 4.

As shown in FIG. 9, the redundancy test output control circuit 21-17 includes selectors 341-1 and 341-2, inverters 342-1, 342-2, 342-3, and 342-4, NAND gates 343-1 and 343-2, an OR gate 344, and a driver 345. The inverter 342-1 inversely buffers a bypass flag BYPF and outputs an inversely buffered bypass flag BYPF. The selector 341-1 selects and outputs one of a bypass output signal WSO-RTLB and a ground voltage VSS based on an output signal of the inverter 342-1. The selector 341-1 selects and outputs the ground voltage VSS when a preset test, for example, a test based on the IEEE 1500 standard, is performed. The inverter 342-2 inversely buffers the ground voltage VSS and outputs an inversely buffered ground voltage VSS. The NAND gate 343-1 and the inverter 342-3 receive an output signal of the selector 341-1 and an output signal of the inverter 342-2 and perform a logical AND operation. The NAND gate 343-1 and the inverter 342-3 buffer and output the output signal of selector 341-1. The NAND gate 343-2 and the inverter 342-4 receive an output signal of the inverter 342-3 and a power supply voltage VDD and perform a logical AND operation. The OR gate 344 receives first to 16^{th} bits B-RP<0:15> of a bump repair signal to operation a logical OR operation. The OR gate 344 outputs a signal of a logic low level when no defect occurs in the first bump to the 16^{th} bump and outputs a signal of a logic high level when a defect occurs in one of the first bump to the 16^{th} bump. The selector 341-2 selects and outputs one of a 16^{th} bit WSO<15> of a test output signal received from the 16^{th} test output control circuit, for example, the 16^{th} test output control circuit 21-16 in FIG. 4, and an output signal of the inverter 342-4 based on an output signal of the OR gate 344. The selector 341-2 selects and outputs the output signal of the inverter 342-4 when no defects occur in the first bump to the 16^{th} bump and the output signal of the OR gate 344 is at a logic low level. The selector 341-2 selects and outputs the 16^{th} bit WSO<15> of the test output signal when a defect occurs in one of the first bump to the 16^{th} bump and the output signal of the OR gate 344 is at a logic high level. The driver 345 drives a redundancy bump test output signal BWSOR according to an output signal of the selector 341-2.

The redundancy test output control circuit 21-17 configured as described above receives the first to 16^{th} bits B-RP<0:15> of the bump repair signal deactivated at a logic low level and the bypass flag BYPF deactivated at a logic low level and outputs the redundancy bump test output signal BWSOR deactivated at a logic low level when a preset test is performed on an activated channel and no defect occurs in the first bump to the 16^{th} bump. In addition, when a preset test is performed on an activated channel and a defect occurs in one of the first bump to the 16^{th} bump, the redundancy test output control circuit 21-17 receives a signal activated at a logic high level among the first to 16^{th} bits B-RP<0:15> of the bump repair signal and outputs the 16^{th} bit WSO<15> of the test output signal received from the 16^{th} test output control circuit 21-16 as the redundancy bump test output signal BWSOR.

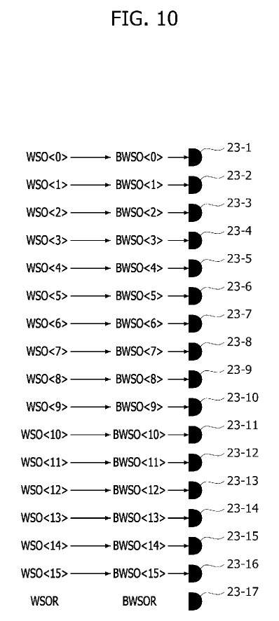

FIG. 10 illustrates an example of an operation in which first to 16^{th} bits BWSO<0:15> of a bump test output signal are output from a bump set 23 while there are no defects in a first bump 23-1 to a 16^{th} bump 23-16.

As shown in FIG. 10, when there is no defect in the first bump 23-1 to the 16^{th} bump 23-16, a first bit BWSO<0> of a bump test output signal generated from a first bit WSO<0> of a test output signal is output through the first bump 23-1, a second bit BWSO<1> of the bump test output signal generated from a second bit WSO<1> of the test output signal is output through the second bump 23-2, a third bit BWSO<2> of the bump test output signal generated from a third bit WSO<2> of the test output signal is output through the third bump 23-3, a fourth bit BWSO<3> of the bump test output signal generated from a fourth bit WSO<3> of the test output signal is output through the fourth bump 23-4, a fifth bit BWSO<4> of the bump test output signal generated from a fifth bit WSO<4> of the test output signal is output through the fifth bump 23-5, a sixth bit BWSO<5> of the bump test output signal generated from a sixth bit WSO<5> of the test output signal is output through the sixth bump 23-6, a seventh bit BWSO<6> of the bump test output signal generated from a seventh bit WSO<6> of the test output signal is output through the seventh bump 23-7, an eighth bit BWSO<7> of the bump test output signal generated from an eighth bit WSO<7> of the test output signal is output through the eighth bump 23-8, a ninth bit BWSO<8> of the bump test output signal generated from a ninth bit WSO<8> of the test output signal is output through the ninth bump 23-9, a tenth bit BWSO<9> of the bump test output signal generated from a tenth bit WSO<9> of the test output signal is output through the tenth bump 23-10, an 11^{th} bit BWSO<10> of the bump test output signal generated from an 11^{th} bit WSO<10> of the test output signal is output through the 11^{th} bump 23-11, a 12^{th} bit BWSO<11> of the bump test output signal generated from a 12^{th} bit WSO<11> of the test output signal is output through the 12^{th} bump 23-12, a 13^{th} bit BWSO<12> of the bump test output signal generated from a 13^{th} bit WSO<12> of the test output signal is output through the 13^{th} bump 23-13, a 14^{th} bit BWSO<13> of the bump test output signal generated from a 14^{th} bit WSO<13> of the test output signal is output through the 14^{th} bump 23-14, a 15^{th} bit BWSO<14> of the bump test output signal generated from a 15^{th} bit WSO<14> of the test output signal is output through the 15^{th} bump 23-15, and a 16^{th} bit BWSO<15> of the bump test output signal generated from a 16^{th} bit WSO<15> of the test output signal is output through the 16^{th} bump 23-16.

When there is no defect in the first bump 23-1 to the 16^{th} bump 23-16, the first to 16^{th} bits BWSO<0:15> of the bump test output signal are generated from the first to sixteenth bits WSO<0:15> of the test output signal, respectively, and the first to 16^{th} bits WSO<0:15> of the test output signal are output to the first bump 23-1 to the 16^{th} bump 23-16, respectively.

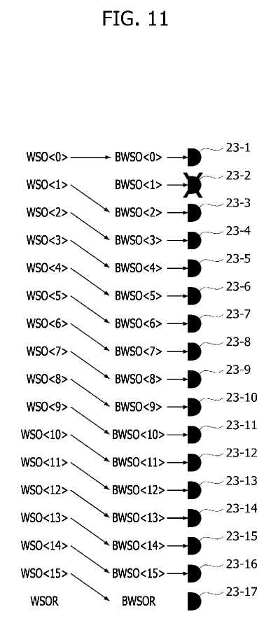

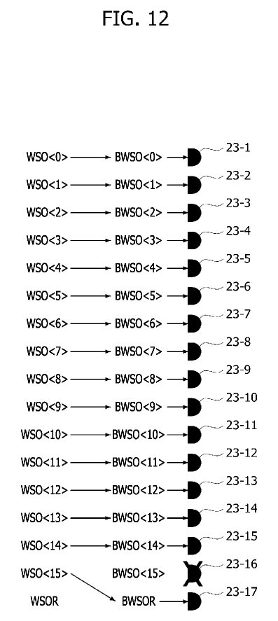

FIGS. 11 and 12 illustrate examples of an operation in which first to 16^{th} bits BWSO<0:15> of a bump test output signal are output from a bump set 23 while there is a defect in one of first bump 23-1 to 16^{th} bump 23-16.

As shown in FIG. 11, when a defect occurs in a second bump 23-2, the first bit BWSO<0> of the bump test output signal generated from a first bit WSO<0> of a test output signal is output through the first bump 23-1, the third bit BWSO<2> of the bump test output signal generated from a second bit WSO<1> of the test output signal is output through the third bump 23-3, the fourth bit BWSO<3> of the bump test output signal generated from a third bit WSO<2> of the test output signal is output through the fourth bump 23-4, the fifth bit BWSO<4> of the bump test output signal generated from a fourth bit WSO<3> of the test output signal is output through the fifth bump 23-5, the sixth bit BWSO<5> of the bump test output signal generated from a fifth bit WSO<4> of the test output signal is output through the sixth bump 23-6, the seventh bit BWSO<6> of the bump test output signal generated from a sixth bit WSO<5> of the test output signal is output through the seventh bump 23-7, the eighth bit BWSO<7> of the bump test output signal generated from a seventh bit WSO<6> of the test output signal is output through the eighth bump 23-8, the ninth bit BWSO<8> of the bump test output signal generated from an eighth bit WSO<7> of the test output signal is output through the ninth bump 23-9, the tenth bit BWSO<9> of the bump test output signal generated from a ninth bit WSO<8> of the test output signal is output through the tenth bump 23-10, the 11^{th} bit BWSO<10> of the bump test output signal generated from a tenth bit WSO<9> of the test output signal is output through the 11^{th} bump 23-11, the 12^{th} bit BWSO<11> of the bump test output signal generated from an 11^{th} bit WSO<10> of the test output signal is output through the 12^{th} bump 23-12, the 13^{th} bit BWSO<12> of the bump test output signal generated from the 12^{th} bit WSO<11> of the test output signal is output through the 13^{th} bump 23-13, the 14^{th} bit BWSO<13> of the bump test output signal generated from a 13^{th} bit WSO<12> of the test output signal is output through the 14^{th} bump 23-14, the 15^{th} bit BWSO<14> of the bump test output signal generated from a 14^{th} bit WSO<13> of the test output signal is output through the 15^{th} bump 23-15, the 16^{th} bit BWSO<15> of the bump test output signal generated from the 15^{th} bit WSO<14> of the test output signal is output through the 16^{th} bump 23-16, and a redundancy bump test output signal BWSOR generated from a 16^{th} bit WSO<15> of the test output signal is output through a 17^{th} bump 23-17.

When a defect occurs in the second bump 23-2, the first bit BWSO<0> of the bump test output signal is generated from the first bit WSO<0> of the test output signal, the second to 16^{th} bits WSO<1:15> of the test output signal are shifted to generate the third to 16^{th} bits BWSO<2:15> of the bump test output signal and the redundancy bump test output signal BWSOR, respectively, the third to 16^{th} bits BWSO<2:15> and the redundancy bump test output signal BWSOR are output to the third bump 23-3 to 17^{th} bump 23-17, respectively, thereby performing a repair or substitute operation of replacing the defective second bump 23-2 with the 17^{th} bump 23-17.

As shown in FIG. 12, when a defect occurs in the 16^{th} bump 23-16, the first bit BWSO<0> of the bump test output signal generated from the first bit WSO<0> of the test output signal is output through the first bump 23-1, the second bit BWSO<1> of the bump test output signal generated from the second bit WSO<1> of the test output signal is output through the second bump 23-2, the third bit BWSO<2> of the bump test output signal generated from the third bit WSO<2> of the test output signal is output through the third bump 23-3, the fourth bit BWSO<3> of the bump test output signal generated from the fourth bit WSO<3> of the test output signal is output through the fourth bump 23-4, the fifth bit BWSO<4> of the bump test output signal generated from the fifth bit WSO<4> of the test output signal is output through the fifth bump 23-5, the sixth bit BWSO<5> of the bump test output signal generated from the sixth bit WSO<5> of the test output signal is output through the sixth bump 23-6, the seventh bit BWSO<6> of the bump test output signal generated from the seventh bit WSO<6> of the test output signal is output through the seventh bump 23-7, the eighth bit BWSO<7> of the bump test output signal generated from the eighth bit WSO<7> of the test output signal is output through the eighth bump 23-8, the ninth bit BWSO<8> of the bump test output signal generated from the ninth bit WSO<8> of the test output signal is output through the ninth bump 23-9, the tenth bit BWSO<9> of the bump test output signal generated from the tenth bit WSO<9> of the test output signal is output through the tenth bump 23-10, the 11^{th} bit BWSO<10> of the bump test output signal generated from the 11^{th} bit WSO<10> of the test output signal is output through the 11^{th} bump 23-11, the 12^{th} bit BWSO<11> of the bump test output signal generated from the 12^{th} bit WSO<11> of the test output signal is output through the 12^{th} bump 23-12, the 13^{th} bit BWSO<12> of the bump test output signal generated from the 13^{th} bit WSO<12> of the test output signal is output through the 13^{th} bump 23-13, the 14^{th} bit BWSO<13> of the bump test output signal generated from the 14^{th} bit WSO<13> of the test output signal is output through the 14^{th} bump 23-14, the 15^{th} bit BWSO<14> of the bump test output signal generated from the 15^{th} bit WSO<14> of the test output signal is output through the 15^{th} bump 23-15, and the redundancy bump test output signal BWSOR generated from the 16^{th} bit WSO<15> of the test output signal is output through the 17^{th} bump 23-17.

When a defect occurs in the 16^{th} bump 23-16, the first to 15^{th} bits BWSO<0:14> of the bump test output signal are generated from the first to 15^{th} bits WSO<0:14> of the test output signal, a redundancy bump test output signal BWSOR is generated by shifting the 16^{th} bit WSO<15> of the test output signal, and the redundancy bump test output signal BWSOR is output to the 17^{th} bump 23-17, thereby performing a repair operation or substitute operation of replacing a defective 16^{th} bump 23-16 with the 17^{th} bump 23-17.

FIG. 13 is a block diagram illustrating a memory system 4 according to an embodiment of the present disclosure.

As shown in FIG. 13, the memory system 4 includes a printed circuit board (PCB) 41, a substrate 43, an interposer 45, a semiconductor device 47, and a processor 49.

The printed circuit board 41 connects various electronic components to each other to form electronic circuits. The electronic circuits may include the memory system 4. A copper (Cu) layer, a solder mask, a silk screen, and so forth are formed on the printed circuit board 41. Circuit paths that transmit or transfer signals or power are formed in the copper (Cu) layer. The solder mask prevents or mitigates damage to the circuits and protects a specific region where components are soldered. The silk screen indicates location or information for the electronic components as characters or symbols printed on a surface of the printed circuit board 41.

The substrate 43 is disposed over the printed circuit board 41 with bumps in between, for example, bumps 411 and mechanically supports the interposer 45, the semiconductor device 47, and the processor 49. The substrate 43 functions as a physical base for the printed circuit board 41 and is an insulator. The substrate 43 may include materials such as flame retardant 4 (FR4) that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 45 is disposed over the substrate 43 with bumps in between and includes wires that connect electronic components, for example, the semiconductor device 47 and the processor 49, that have form factors or pin arrangements do not match or have different spacing. The interposer 45 may convert signals to communicate on different interfaces, such as double data rate (DDR), high bandwidth memory (HBM), peripheral component interconnect express (PCle).

The semiconductor device 47 is disposed over the interposer 45 with pads in between, for example, micro-bumps 413. The semiconductor device 47 stores data received from the processor 49 or outputs the stored data to the processor 49 under control of the processor 49. The semiconductor device 47 includes a base die 420 and a plurality of core dies 421-1 to 421-L, where L is an integer greater than 1. The core dies 421-1 to 421-L are stacked over the base die 420 with micro-bumps in between. The base die 420 and the core dies 421-1 to 421-L are vertically connected to each other using through vias and micro-bumps. The base die 420 controls efficient data transmission between the processor 49 and the core dies 421-1 to 421-L. The base die 420 receives input/output power voltage (voltage drain drain for IO also referred to as output stage drain power voltage) VDDQ as an operating voltage utilized during operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 to 421-L use a peripheral voltage VPERI as an operating voltage during operation of the internal circuits included in the core dies 421-1 to 421-L. The core dies 421-1 to 421-L generate the peripheral voltage VPERI from the power supply voltage VDD received through the base die 420. The core dies 421-1 to 421-L generate the peripheral voltage VPERI at a lower voltage level than the input/output power voltage VDDQ and use the peripheral voltage VPERI as an operating voltage. Each of the core dies 421-1 to 421-L may include a plurality of channel regions, for example, eight channel regions or sixteen channel regions that operate independently. Each of the plurality of channel regions is allocated with a channel operating independently to receive or transmit data. The number L of core dies 421-1 to 421-L may be four, eight, twelve, sixteen, and so forth. For example, when each of the core dies 421-1 to 421-12 has eight channels, the core dies 421-1 to 421-4, the core dies 421-5 to 421-8, and the core dies 421-9 to 421-12 each include thirty two channel regions, and transmit and receive data with the processor 49 in units of a rank including thirty two channels. The base die 420 may be implemented with the base die 1 shown in FIG. 1, and may include the test interface circuit 10 illustrated in FIG. 2. When a defect occurs in a bump from which a bump test output signal is output, the base die 420 can repair or substitute the defect in the bump by replacing the defective bump with a redundant bump. In an embodiment, when a defect occurs in a micro-bump from which a bump test output signal is output, the base die 420 can repair the defect in the micro-bump by replacing the defective micro-bump with a redundant micro-bump.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A semiconductor device comprising:
a plurality of core dies stacked over a base die,
wherein the base die comprises a test interface circuit configured to perform a preset test based on a test information signal extracted from a test input signal and output a plurality of test result signals generated as a result of performing the preset test on a plurality of bumps, and
wherein the test interface circuit shifts one or more of the plurality of test result signals to substitute a defective bump with a redundant bump when a defect occurs in one of the plurality of bumps.

2. The semiconductor device of claim 1, wherein the test interface circuit comprises a test input decoder configured to receive the test input signal as serial data, extract channel selection information and instruction information from the test input signal, and output the channel selection information and instruction information as the test information signal.

3. The semiconductor device of claim 1, wherein the test interface circuit comprises a test control circuit configured to generate and output the plurality of test result signals according to a result of the test performed based on the test information signal.

4. The semiconductor device of claim 1, wherein the test interface circuit comprises a test output control circuit configured to output the plurality of test result signals as a plurality of bump test output signals when the test is performed on an activated channel and no defect occurs in the plurality of bumps.

5. The semiconductor device of claim 4, wherein the test output control circuit outputs the plurality of bump test output signals to the plurality of bumps.

6. The semiconductor device of claim 4, wherein when the test is performed on an activated channel and a defect occurs in the plurality of bumps, the test output control circuit shifts the plurality of test result signals according to a bump repair signal and outputs shifted plurality of test result signals as the bump test output signal and a redundancy bump test output signal.

7. The semiconductor device of claim 6, wherein the test interface circuit further comprises a bump repair signal generation circuit configured to store information on whether the plurality of bumps are defective and generate the bump repair signal based on the information on whether the plurality of bumps are defective.

8. The semiconductor device of claim 4, wherein the test output control circuit comprises:
a first test output control circuit configured to output a first bit of the test result signal as a first bit of a test output signal and generate a first bit of a bump test output signal depending on whether a first bump is defective;
a second test output control circuit configured to output a second bit of the test result signal as a second bit of the test output signal and generate a second bit of the bump test output signal depending on whether at least one of the first bump and a second bump is defective; and
a redundancy test output control circuit configured to generate a redundancy bump test output signal depending on whether at least one of the first bump and the second bump is defective.

9. The semiconductor device of claim 8, wherein the first test output control circuit outputs the first bit of the test output signal as the first bit of the bump test output signal when no defect occurs in the first bump.

10. The semiconductor device of claim 8, wherein the first test output control circuit generates the first bit of the bump test output signal as deactivated when a defect occurs in the first bump.

11. The semiconductor device of claim 8, wherein the second test output control circuit outputs the second bit of the test output signal as the second bit of the bump test output signal when no defect occurs in the first bump and the second bump.

12. The semiconductor device of claim 8, wherein the second test output control circuit generates the second bit of the bump test output signal as deactivated when a defect occurs in the second bump.

13. The semiconductor device of claim 8, wherein the second test output control circuit outputs the first bit of the test output signal as the second bit of the bump test output signal when a defect occurs in the first bump.

14. The semiconductor device of claim 8, wherein the redundancy test output control circuit generates the redundancy bump test output signal as deactivated when no defect occurs in the first bump and the second bump.

15. The semiconductor device of claim 8, wherein the redundancy test output control circuit outputs the second bit of the test output signal as the redundancy bump test output signal when a defect occurs in the first bump or the second bump.

16. The semiconductor device of claim 8,
further comprising a bump set,
wherein the bump set comprises:
the first bump from which the first bit of the bump test output signal is output;
the second bump from which the second bit of the bump test output signal is output; and
a redundancy bump from which the redundancy bump test output signal is output.

17. A semiconductor device comprising:
a test input decoder configured to receive a test input signal as serial data, extract channel selection information and instruction information from the test input signal, and output the channel selection information and the instruction information as a test information signal;
a test control circuit configured to generate and output a plurality of test result signals according to a result of a test performed based on the test information signal; and
a test output control circuit configured to output the plurality of test result signals as bump test output signals when the test is performed on an activated channel and no defect occurs in a plurality of bumps,
wherein the test output control circuit shifts the plurality of test result signals according to a bump repair signal to output the bump test output signal and a redundancy bump test output signal when a defect occurs in the plurality of bumps.

18. The semiconductor device of claim 17, further comprising a bump repair signal generation circuit configured to store information on whether the plurality of bumps are defective and generate the bump repair signal based on the information on whether the plurality of bumps are defective.

19. The semiconductor device of claim 17, wherein the test output control circuit comprises:
a first test output control circuit configured to output a first bit of the test result signal as a first bit of a test output signal and generate a first bit of the bump test output signal depending on whether the first bump is defective;
a second test output control circuit configured to output a second bit of the test result signal as a second bit of the test output signal and generate a second bit of the bump test output signal depending on whether the first bump and the second bump are defective; and
a redundancy test output control circuit configured to generate the redundancy bump test output signal depending on whether the first bump and the second bump are defective.

20. The semiconductor device of claim 19, wherein the first test output control circuit outputs the first bit of the test output signal as the first bit of the bump test output signal when no defect occurs in the first bump.

21. The semiconductor device of claim 19, wherein the first test output control circuit generates the first bit of the bump test output signal as deactivated when a defect occurs in the first bump.

22. The semiconductor device of claim 19, wherein the second test output control circuit outputs the second bit of the test output signal as the second bit of the bump test output signal when no defect occurs in the first bump and the second bump.

23. The semiconductor device of claim 19, wherein the second test output control circuit generates the second bit of the bump test output signal as deactivated when a defect occurs in the second bump.

24. The semiconductor device of claim 19, wherein the second test output control circuit outputs the first bit of the test output signal as the second bit of the bump test output signal when a defect occurs in the first bump.

25. The semiconductor device of claim 19, wherein the redundancy test output control circuit generates the redundancy bump test output signal in a deactivated state when no defect occurs in the first bump and the second bump.

26. The semiconductor device of claim 19, wherein the redundancy test output control circuit outputs the second bit of the test output signal as the redundancy bump test output signal when a defect occurs in the first bump or the second bump.

27. The semiconductor device of claim 19,
further comprising a bump set,
wherein the bump set comprises:
the first bump from which the first bit of the bump test output signal is output;
the second bump from which the second bit of the bump test output signal is output; and
a redundancy bump from which the redundancy bump test output signal is output.

28. A semiconductor device comprising:
a plurality of core dies stacked over a base die,
wherein the base die comprises a test interface circuit configured to perform a preset test based on a test information signal extracted from a test input signal and output a first bit of a test result signal and a second bit of the test result signal generated as a result of performing the test on a first bump and a second bump, and
wherein the test interface circuit outputs the first bit of the test result signal to the second bump and outputs the second bit of the test result signal to a redundancy bump when a defect occurs in the first bump.

29. The semiconductor device of claim 28, wherein the test interface circuit deactivates a first bit of a bump test output signal output to the first bump when a defect occurs in the first bump.

30. The semiconductor device of claim 28, wherein the test interface circuit outputs the first bit of the test result signal to the first bump when a defect occurs in the second bump, and outputs the second bit of the test result signal to the redundancy bump.

31. The semiconductor device of claim 30, wherein the test interface circuit deactivates a second bit of the bump test output signal output to the second bump when a defect occurs in the second bump.

32. The semiconductor device of claim 28, wherein the test interface circuit outputs the first bit of the test result signal to the first bump and outputs the second bit of the test result signal to the second bump when no defect occurs in the first bump and the second bump.
